(19) United States
(12) Patent Application Publication
(10) Pub. No.: US 2007/0004194 A1
(43) Pub. Date: Jan. 4, 2007

(54) Method for fabricating semiconductor device with deep opening

(76) Inventors: Yong-Tae Cho, Ichon-shi (KR); Hae-Jung Lee, Ichon-shi (KR); Sang-Hoon Cho, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/321,593

(22) Filed: Dec. 30, 2005

(30) Foreign Application Priority Data
Jun. 30, 2005 (KR) 2005-0058886
Jun. 30, 2005 (KR) 2005-0058893

(51) Int. Cl. H01L 21/4763

(52) U.S. Cl. 438/624

(57) ABSTRACT

A method for fabricating a semiconductor device with a deep opening is provided. The method includes: forming an insulation layer on a substrate; selectively etching the insulation layer to form first openings; enlarging areas of the first openings; forming anti-bowing spacers on sidewalls of the enlarged first openings; and etching portions of the insulation layer remaining beneath the enlarged first openings to form second openings.

This application claims the benefit of Korean patent application Nos. KR 2005-58886 and KR 2005-58893, both filed in the Korean Patent Office on Jun. 30, 2005, the entire contents of which are incorporated herein by reference.

1. Technical Field

The present invention relates to a method for fabricating a semiconductor device; and, more particularly, to a method for fabricating a semiconductor device with a deep contact hole.

2. Description of Related Arts

As the design rule of dynamic random access memories (DRAM) has been decreased, the thickness of a photoresist pattern used as a mask for forming contact holes has also been decreased. Thus, if the photoresist pattern is solely used for forming contact holes, an insufficient thickness margin of the photoresist pattern results. For this reason, hard masks are currently used when forming the contact holes. However, if the hard masks remain after the contact hole formation, the presence of the hard masks often causes interfacial layers from being lifted up due to the different stress levels between them. Accordingly, a removal of the hard masks also becomes important.

In a recent capacitor process in DRAMs, hard masks for forming storage node contact holes are formed of polysilicon or nitride. The storage node contact holes are contact holes that provide three-dimensional structures where storage nodes are to be formed and connect the storage nodes with storage node contact plugs.

FIGS. 1A and 1B are cross-sectional views illustrating a method for fabricating a capacitor in a conventional semiconductor device.

Referring to FIG. 1A, a first insulation layer 12 is formed on a substrate 11 which further includes, transistors and bit lines formed therein. Storage node contact holes are formed by etching the first insulation layer 12, and a storage node contact plug material is filled into the storage node contact holes, thereby forming storage node contact plugs 13. Although not illustrated, the first insulation layer 12 is formed in a multi-layer structure since the bit lines, the transistors and the word lines are already prepared prior to forming the first insulation layer 12.

Further detailing the formation of the storage node contact plugs 13, a polysilicon layer is formed over the first insulation layer 12 and in the storage node contact holes. Then, an etch-back process or a chemical mechanical polishing (CMP) process is performed to remove the polysilicon layer over first insulating layer 12, thereby forming storage node contact plugs 13.

An etch stop layer 14 is formed on the storage node contact plugs 13 and the first insulation layer 12. A second insulation layer 15 and a third insulation layer 16 are sequentially formed on the etch stop layer 14 to form capacitor structures. The etch stop layer 14 is formed of silicon nitride and acts as an etch barrier when the second insulation layer 15 and the third insulation layer 16 are etched. The second insulation layer 15 and the third insulation layer 16 provide three-dimensional structures where storage nodes are to be formed. The second insulation layer 15 is a phosphosilicate glass (PSG) layer and the third insulation layer 16, is a tetraethyl orthosilicate (TEOS) layer.

Hard masks 17 are formed on the third insulation layer 16. In forming the hard masks 17, although not illustrated, a hard mask layer is formed on the third insulation layer 16 and a photoresist layer is formed thereon. Using a mask, the photoresist layer is patterned using a photo-exposure and developing process. The hard mask layer is then etched using the photoresist pattern as an etch mask, thereby obtaining the hard masks 17.

The third insulation layer 16 and the second insulation layer 15 are etched to have a high aspect ratio using the hard masks 17 as an etch mask. Reference numeral 18 denotes contact holes formed by the above etching process. A wet etching process is used to maximize the area of each of the contact holes 18. Afterwards, the hard masks 17 are removed, and the etch stop layer 14 is etched to expose the storage node contact plugs 13.

Referring to FIG. 1B, lower electrodes 19 are formed in the contact holes 18, and the third insulation layer 16 and the second insulation layer 15 are removed by a wet dip-out process.

As shown above, as the pattern size has been scaled down, the size of a contact for a cylinder-type capacitor having a high aspect ratio (e.g., a metal-insulator-metal (MIM) type capacitor) has also been decreased. Thus, as shown in FIGS. 1A and 1B, the areas of the contact holes 18 and the heights of the capacitors are increased.

However, increasing the areas of the contact holes 18 often results in a generation of bridges between the neighboring capacitors due to the insufficient dimension between the capacitors. This bridge generation ‘X’ is illustrated in FIG. 2A. Also, increasing the heights of the capacitors often results in an improper opening of the contact holes. This improper opening ‘Y’ of the contact holes is illustrated in FIG. 2B.

Furthermore, the above limitations may bring out a dual bit failure, a single bit failure, or a direct current (DC) failure, resulting in a decrease in the yield rate of semiconductor devices.

### SUMMARY

Consistent with an embodiment of the present invention, there is provided a method for fabricating a semiconductor device with a deep contact hole, wherein the method can prevent a generation of bridges between capacitors and an improper opening of a contact hole.

Also consistent with an embodiment of the present invention, there is provided a method for manufacturing a semiconductor device, including: forming an insulation layer on a substrate; selectively etching the insulation layer to form first openings; enlarging areas of the first openings; forming anti-bowing spacers on sidewalls of the enlarged first openings; and etching portions of the insulation layer remaining beneath the enlarged first openings to form second openings.

Further consistent with an embodiment of the present invention, there is provided a method for fabricating a semiconductor device, including: forming an insulation layer on a substrate; selectively etching the insulation layer to form first openings; enlarging areas of the first openings; forming anti-bowing spacers on sidewalls of the enlarged first openings; etching portions of the insulation layer remaining beneath the enlarged first openings to form second openings; forming lower electrodes on bottom portions and sidewalls of opening regions, each opening region including the enlarged first opening and the second opening; and sequentially forming a dielectric layer and an upper electrode on the lower electrodes.

### BRIEF DESCRIPTION OF THE DRAWINGS

The above and other features of the present invention will become better understood with respect to the following description of the preferred embodiments given in conjunction with the accompanying drawings, in which:

FIGS. 1A and 1B are cross-sectional views illustrating a conventional method for fabricating a capacitor of a semiconductor device;

FIG. 2A is a diagram showing a generation of a bridge between capacitors;

FIG. 2B is a diagram showing an improper opening of a contact hole; and

FIGS. 3A to 3F are cross-sectional views illustrating a method for fabricating a capacitor of a semiconductor device in accordance with a specific embodiment consistent with the present invention.

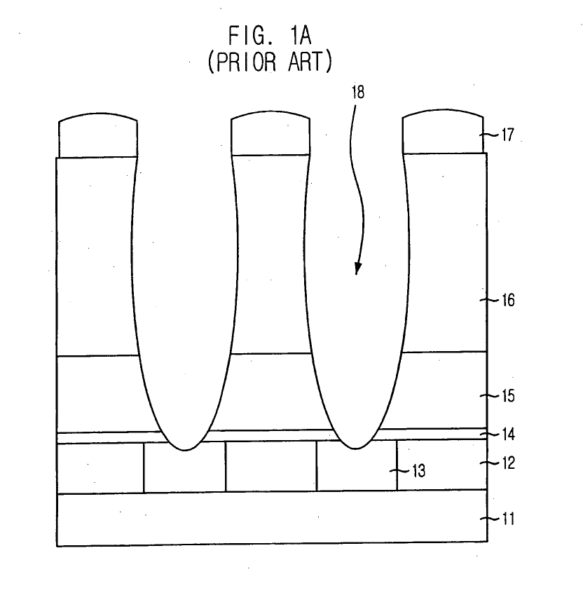

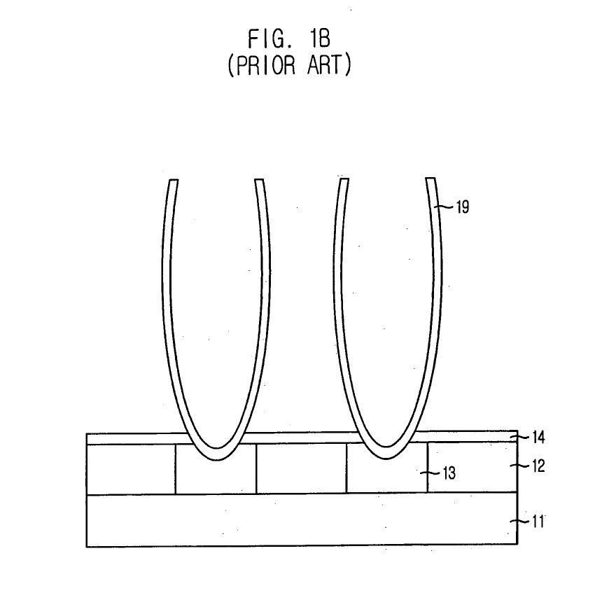

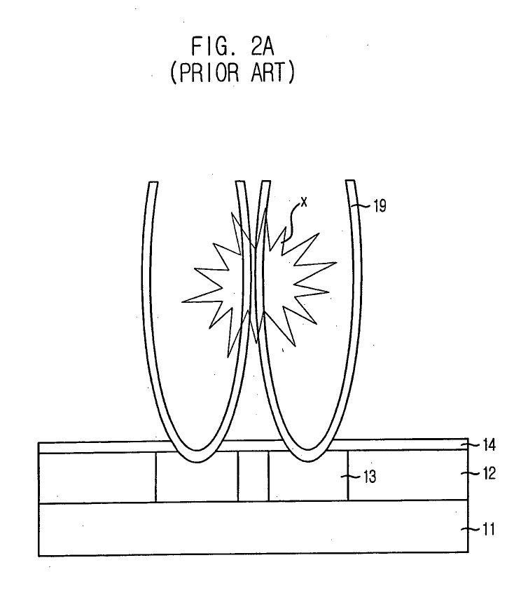

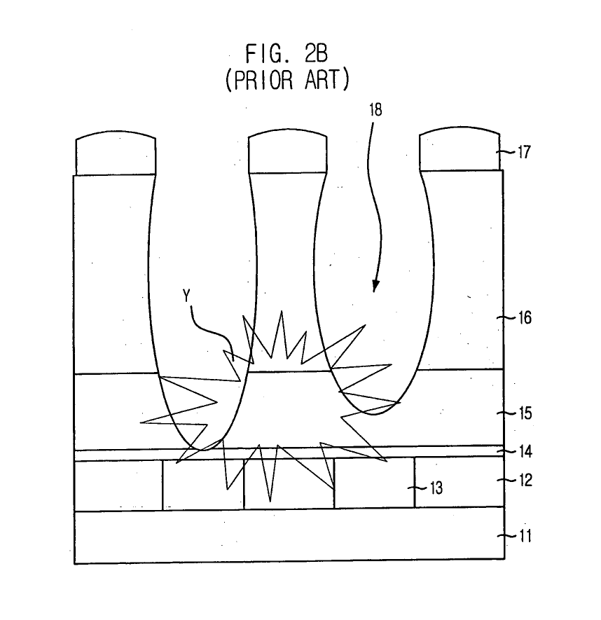

### DETAILED DESCRIPTION

A method for fabricating a semiconductor device with a deep contact hole in accordance with exemplary embodiments consistent with the present invention will be described in detail with reference to the accompanying drawings.

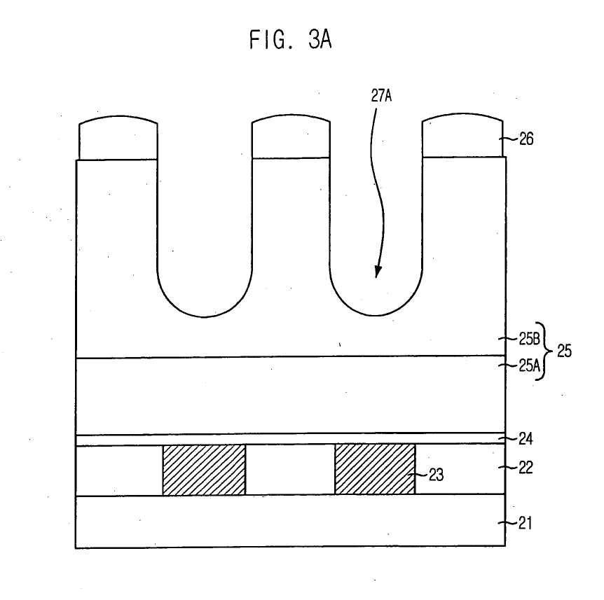

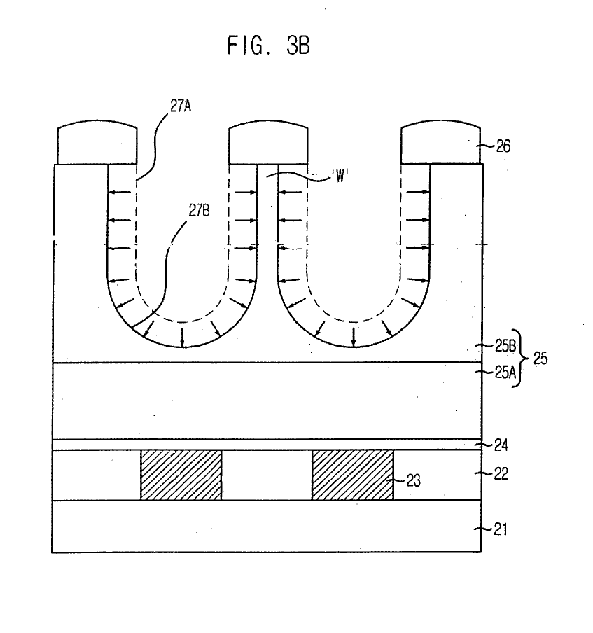

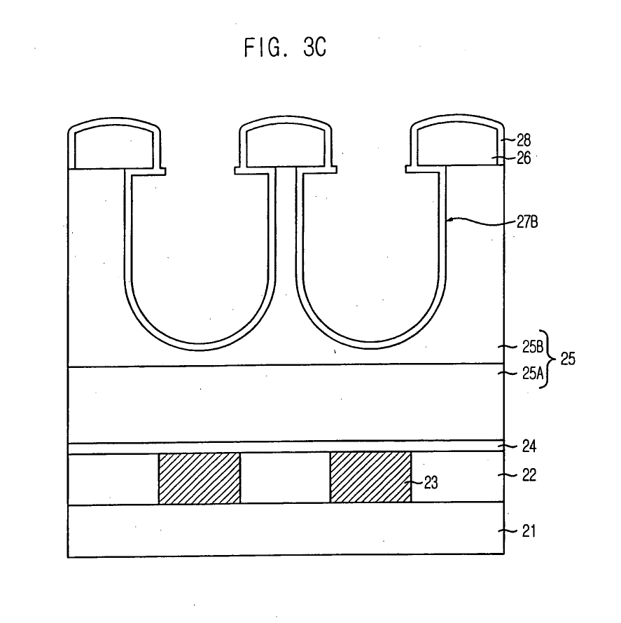

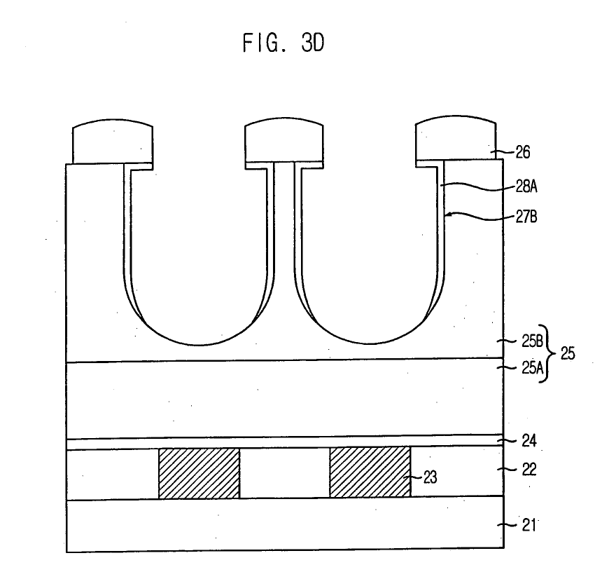

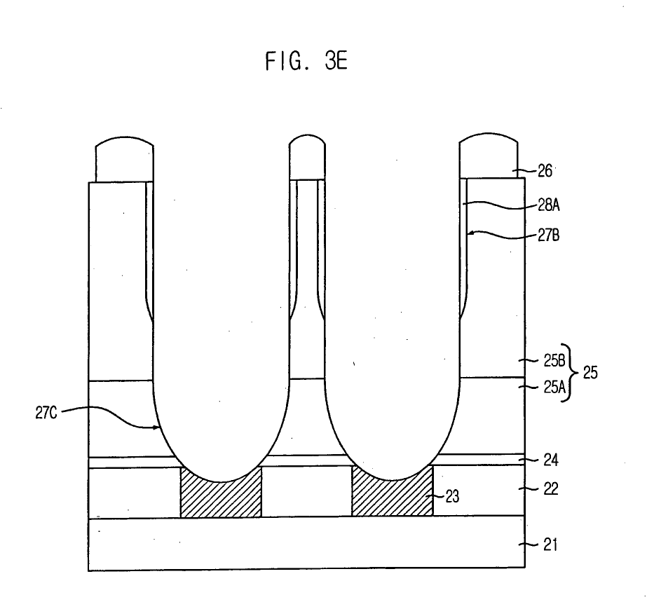

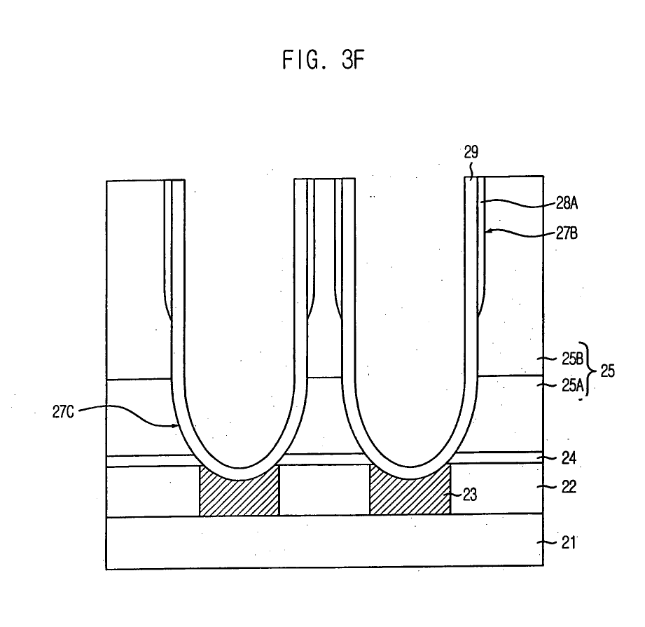

FIGS. 3A and 3F are cross-sectional views illustrating a method for fabricating a capacitor in a semiconductor device in accordance with a specific embodiment consistent with the present invention.

Referring to FIG. 3A, a first insulation layer 22 is formed on a substrate 21. The substrate 21 includes word lines, transistors and bit lines formed therein. Although not illustrated, the first insulation layer 22 is etched to form storage node contact holes. A storage node contact plug material is then formed over the first insulation layer 22, filling the storage node contact holes. The storage node contact plug material may be polysilicon. An etch-back process or a chemical mechanical polishing (CMP) process is performed on the storage node contact material, and as a result, storage node contact plugs 23 are formed. Also, although not illustrated, the first insulation layer 22 has a multi-layer structure since the word lines, the transistors and bit lines are formed prior to the formation of the first insulation layer 22.

An etch stop layer 24 is formed on the first insulation layer 22 and the storage node contact plugs 23. A second insulation layer 25 for use in a capacitor is formed on the etch stop layer 24. The etch stop layer 24 functions as an etch barrier when the second insulation layer 25 is etched and may include silicon nitride. The second insulation layer 25 provides three dimensional structures where storage nodes are to be formed. The second insulation layer 25 is formed in a stack structure including a first layer 25A and a second layer 25B. The first layer 25A and the second layer 25B respectively include phosphosilicate glass (PSG) and tetraethyl orthosilicate (TEOS).

Hard masks 26 are then formed on the second insulation layer 25. In forming the hard masks 26, a photoresist layer is formed on a hard mask layer and patterned by a photo-exposure and developing process. Using the photoresist pattern as an etch mask, the hard mask layer can be etched to form the hard masks 26. The hard masks 26 are employed to form deep contact holes having a high aspect ratio. The hard masks 26 can include polysilicon. Also, the etching process for forming the hard masks 26 can be a reactive ion etching (RIE) process carried out at a pressure of approximately 20 mTorr. with supplying a source power of approximately 450 W and a bias power of approximately 50 W. Also, this etching process utilizes a gas mixture obtained by mixing approximately 350 sccm of hydrogen bromide (HBr), approximately 10 sccm of chlorine (Cl₂) and approximately 3 sccm of oxygen (O₂).

The photoresist pattern is stripped, and a portion of the second insulation layer 25 is etched using the hard masks 26 as an etch mask, thereby forming first openings 27A, which have a vertical profile. More specifically, this etching process (hereinafter referred to as “first etching process”) is performed such that the second layer 25B is partially etched and a portion of the second layer 25B with a predetermined thickness remains on the first layer 25A.

In the first etching process, a gas mixture of CₓF_{y} gas and O₂ gas may be supplied into a magnetically enhanced reactive ion etching (MERIE) plasma source to form a high density plasma (HDP), and thus, sidewalls of the first openings 27A can be etched to a have a vertical profile. A ratio of a flow quantity of the CₓF_{y} gas to the O₂ gas is approximately 1 to 1. Particularly, the flow quantity of the CₓF_{y} gas is higher than that of the O₂ gas. The CₓF_{y} gas includes one selected from the group consisting of CF₄, C₄F₈, C₄F₆, C₅F₈, and a combination thereof. For instance, the first etching process is carried out using a gas mixture mixture, which is obtained by mixing approximately 34 sccm of C₄F₆ gas, approximately 35 sccm of O₂ gas, approximately 14 sccm of CF₄ gas, and approximately 550 sccm of Ar gas, at a pressure of approximately 15 mTorr and supplying a source power of approximately 1,300 W and a bias power of approximately 1,800 W.

Referring to FIG. 3B, an isotropic etching process is performed with a wet etching apparatus using a wet chemical selected from buffer oxide etchant (BOE) or hydrogen fluoride (HF). As a result, the areas of the first openings 27A are enlarged. The enlarged first openings 27A will be referred to as “second openings 27B” hereinafter. The first openings 27A are enlarged up to a size ‘W’ that causes no bridge generation between capacitors. Particularly, the size ‘W’ can be equal to or greater than approximately 10 nm, which is the size that allows electrical insulation.

Table 1 below shows various exemplary isotropic etching conditions for enlarging the first openings 27A in accordance with the present invention.

TABLE 1

| Chemicals | PE-TEOS E/R | 10 nm TG | 20 nm TG | 30 nm TG | 40 nm TG | 50 nm TG | 60 nm TG |
|---|---|---|---|---|---|---|---|
| BOE diluted in a ratio | 20 Å/s | 10 seconds | 20 seconds | 30 seconds | 40 seconds | 50 seconds | 60 seconds |
| of approximately 20:1 | | | | | | | |
| BOE diluted in a ratio | 1.25 Å/s | 160 seconds | 320 seconds | 480 seconds | 640 seconds | 800 seconds | 960 seconds |
| of approximately 300:1 | | | | | | | |
| HF diluted in a ratio | 4.5 Å/s | 44 seconds | 89 seconds | 133 seconds | 178 seconds | 222 seconds | 267 seconds |
| of approximately 100:1 | | | | | | | |

Herein, ‘TG’ and ‘PE-TEOS E/R’ represent a target and an etch rate of a plasma enhanced tetraethyl orthosilicate layer, respectively.

For instance, the isotropic etching process can be performed for approximately 170 seconds using HF solution diluted in a ratio of approximately 100 parts of a dilution agent to approximately 1 part of HF. According to this isotropic etching condition, the area of the first openings can be increased by-approximately 40 nm.

Referring to FIG. 3C, an anti-bowing layer 28 is formed on the hard masks 26 and on the second openings 27B. The anti-bowing layer 28 prevents a bowing from occurring and is formed to a thickness ranging from approximately 100 Å to approximately 200 Å. The anti-bowing layer 28 includes a material identical to a lower electrode material, and thus, the anti-bowing layer 28 may be used as a lower electrode. For instance, the anti-bowing layer 28 includes a material selected from the group consisting of titanium nitride (TiN), tungsten (W), ruthenium (Ru), and iridium (Ir). In the present embodiment, it is assumed that the anti-bowing layer 28 includes TiN.

Referring to FIG. 3D, the anti-bowing layer 28 is etched to form anti-bowing spacers 28A on sidewalls of the second openings 27B. The etching of the anti-bowing layer 28 is carried out by using a high density plasma obtained by injecting a gas mixture of Cl₂ gas and Ar gas into a transformer coupled plasma (TCP)/inductively coupled plasma. (ICP) plasma source. A mixing ratio of the Cl₂ gas to the Ar gas ranges between approximately 1:10 to approximately 1:20. Also, the anti-bowing layer 28 is etched at a pressure of approximately 10 mTorr, a source power of approximately 300 W and a bias power of approximately 100 W and with a gas mixture including approximately 190 sccm of the Ar gas and approximately 10 sccm of the Cl₂ gas. The reason for providing the Ar gas in a higher ratio than the Cl₂ gas is to increase directionality of the high density plasma, so that portions of the anti-bowing layer 28 (i.e., the TiN layer) disposed on the bottom and outside of the second openings 27B are etched at a higher rate than portions of the anti-bowing layer 28 disposed on the sidewalls of the second openings 27B. As a result, the anti-bowing spacers 28A are formed on the sidewalls of the second openings 27B.

Referring to FIG. 3E, the second insulation layer 25 is etched again using the anti-bowing spacers 28A and the hard masks 26 as an etch mask. The etching of the second insulation layer 25 (hereinafter referred to as “second etching process”) is stopped at the etch stop layer 24. The etch stop layer 24 disposed below the second openings 27B is etched to form third openings 27C exposing the storage node contact plugs 23. The third openings 27C provide the final three dimensional structures where the lower electrodes are to be formed.

The second etching process is carried out using a high density plasma obtained by injecting a gas mixture of CₓF_{y} gas and O₂ gas into an MERIE plasma source. At this time, the anti-bowing spacers 28A serve as an anti-bowing layer due to a high etch selectivity of the second insulation layer 25 to the anti-bowing spacers 28A. For instance, the etch selectivity may be greater than approximately 200:1. Thus, it is possible to obtain a vertical etch profile of the third openings 27C with a maximal opening margin, which may prevent an opening from not properly forming.

The CₓF_{y} gas can include one selected from the group consisting of CF₄, C₄F₈, C₅F₈, CHF₃, and CH₂F₂, and induces a generation of lots of CHₓ radicals, so that the CₓF_{y} gas gives a high etch selectivity of the second insulation layer 25 to the anti-bowing spacers 28A and an faster etch rate for the second insulation layer 25.

The etching of the second insulation layer 25 using the CₓF_{y} gas utilizes the following chemical mechanism.
CF: SiO₂+4CF→SiF₄+2CO⇑+2C
CF2: SiO₂+2CF₂→SiF₄+2CO⇑
CF3: 3SiO₂+4CF₃→3SiF₄+4O₂+4CO⇑

For instance, a remaining portion of the second insulation layer 25 is etched using a gas mixture at approximately 15 mTorr with a source power of approximately 1,700 W and a bias power of approximately 2,300 W. The gas mixture is obtained by mixing approximately 34 sccm of C₄F₆ gas, approximately 31 sccm of O₂ gas, approximately 16 sccm of CF₄ gas, and approximately 400 sccm of Ar gas.

Referring to FIG. 3F, the aforementioned lower electrodes 29 are formed on the bottom and sidewalls of the second and third openings 27B and 27C. Although not illustrated, a dielectric layer and an upper electrode are also formed.

The capacitors according to the present embodiment are obtained using an enlarged nitride half spacer scheme because of the anti-bowing spacers 28A formed on the sidewalls of the lower electrodes 29. Table 2 below shows comparison results for comparing characteristics of a capacitor fabricated by the present embodiment with characteristics of a conventional capacitor.

TABLE 2

| | Conventional | Present |
|---|---|---|
| | method | embodiment |
| Minimum inter-capacitor | 50 nm | 25 nm |
| distance (top view) | | |
| Minimum inter-capacitor | 20 nm | 18 nm |
| distance (cross-sectional view) | | |
| Degree of bowing | 13 nm/side | 1 nm/side |
| Degree of improvement | A fF | (A + 10) fF |
| on capacitance | | |

Herein, ‘A’ expresses a certain level of capacitance.

As shown in Table 2, with respect to a top view of the capacitors fabricated consistent with the present embodiment, a minimum distance between the capacitors can be reduced from 50 nm to approximately 25 nm. With respect to a cross-sectional view of the capacitors, a minimum distance between the capacitors can be reduced from 20 nm to approximately 18 nm. Also, consistent with the present embodiment, the degree of bowing can be reduced from 13 nm to about 1 nm and the capacitance can be improved by approximately 10 fF.

In accordance with another embodiment consistent with the present invention, the anti-bowing layer 28 can include a nitride-based material and may be formed to a thickness of approximately 100 Å to approximately 200 Å on the second openings 27B and the hard masks 26.

When the anti-bowing layer 28 includes the nitride-based material, the etching of the anti-bowing layer 28 is carried out using a high density plasma obtained by injecting a gas mixture of CₓF_{y} gas, CHₓF_{y} gas and O₂ gas into an MERIE plasma source. For instance, the etching of the anti-bowing layer 28 may be carried out at a pressure of approximately 50 mTorr, and a source power of approximately 500 W of power, and using a gas mixture obtained by mixing approximately 100 sccm of Ar gas, approximately 20 sccm of CHF₃ gas and approximately 8 sccm of O₂ gas. As a result of this etching process, the anti-bowing spacers 28A are formed on sidewalls of the second openings 27B, and bottom portions of the second openings 27B are opened.

Consistent with the, exemplary embodiments of the present invention, anti-bowing -spacers are formed when deep contact holes are formed for capacitor contacts. In addition to the capacitor contacts, methods consistent with the present invention are also applicable for forming deep contact holes with a size of greater than approximately 30,000 Å. For instance, in the case of a metal line process, openings are contact holes.

On the basis of the exemplary embodiments consistent with the present invention, prior to a complete opening of contact holes or openings, the contact holes or openings are enlarged using a wet etching process. Since anti-bowing spacers are formed on sidewalls of the contact holes or openings, it may be possible to realize a profile of openings that are maximally opened.

While the present invention has been described with respect to certain preferred embodiments, it will be apparent to those skilled in the art that various changes and modifications may be made without departing from the spirit and scope of the invention as defined in the following claims.

What is claimed is:

1. A method for manufacturing a semiconductor device, comprising:
forming an insulation layer on a substrate;
selectively etching the insulation layer to form first openings;
enlarging areas of the first openings;
forming anti-bowing spacers on sidewalls of the enlarged first openings; and
etching portions of the insulation layer remaining beneath the enlarged first openings to form second openings.

2. The method of claim 1, wherein forming the insulation layer comprises:
forming a first insulation layer on the substrate;
forming an etch stop layer on the first insulation layer; and
forming a second insulation layer for use in a capacitor on the etch stop layer, the second insulation layer including a third insulation layer and a fourth insulation layer.

3. The method of claim 2, wherein forming the first openings comprises:
forming hard masks on the fourth insulation layer; and
selectively etching the fourth insulation layer using the hard masks as an etch mask such that a portion of the fourth insulation layer having a predetermined thickness remains at the bottom of the first openings.

4. The method of claim 3, wherein forming the first insulation layer comprises forming the first insulation layer having a multi-layer structure.

5. The method of claim 3, wherein forming the third insulation layer comprises forming a layer of phosphosilicate glass (PSG) and forming the fourth insulation layer includes forming a layer of tetraethyl orthosilicate (TEOS).

6. The method of claim 1, wherein forming the fist openings comprises injecting a gas mixture of CₓF_{y}/O₂ into a magnetically enhanced reactive ion etching (MERIE) plasma source.

7. The method of claim 6, wherein a ratio of a flow quantity of the CₓF_{y} gas to the O₂ gas is approximately 1 to 1.

8. The method of claim 7, wherein the CₓF_{y} gas is selected from the group consisting of CF₄, C₄F₈, C₄F₆, and C₅F₈.

9. The method of claim 1, wherein enlarging the areas of the first openings comprises employing an isotropic etching process using a wet chemical.

10. The method of claim 9, wherein the wet chemical is one of buffered oxide etchant (BOE) and hydrogen fluoride (HF)

11. The method of claim 9, wherein-enlarging the areas of the first openings comprises enlarging the areas until a width between adjacent first openings is at least 10 nm.

12. The method of claim 1, wherein forming the anti-bowing spacers comprises:
forming an anti-bowing layer on the enlarged first openings and on the hard masks; and
selectively etching portions of the anti-bowing layer disposed on the hard masks and on bottom portions of the enlarged first openings to form the anti-bowing spacers on the sidewalls of the enlarged first openings.

13. The method of claim 12, wherein forming the anti-bowing layer comprises forming a layer comprising the same material used to form lower electrodes, so that the anti-bowing layer prevents a bowing incidence and functions as the lower electrodes.

14. The method of claim 13, wherein the anti-bowing layer includes one selected from the group consisting of titanium nitride (TiN), tungsten (W), ruthenium (Ru), and iridium (Ir).

15. The method of claim 14, wherein the selective etching of the anti-bowing layer comprises using a high density plasma obtained by injecting a gas mixture of Cl₂/Ar in a predetermined ratio into a transformer coupled plasma (TCP)/inductively coupled plasma (ICP) plasma source.

16. The method of claim 15, wherein the predetermined mixing ratio of the Cl₂ gas to the Ar gas ranges between approximately 1:10 and approximately 1:20.

17. The method of claim 12, wherein the anti-bowing layer includes a nitride-based material.

18. The method of 17, wherein etching the anti-bowing layer comprises using a high density plasma obtained by injecting a gas mixture of CₓF_{y}/CHₓF_{y}/O₂ gas into an MERIE plasma source.

19. The method of claim 12, wherein forming the anti-bowing layer comprises forming the anti-bowing layer to a thickness ranging from approximately 100 Å to approximately 200 Å.

20. The method of claim 3, wherein the forming of the second openings comprises:
etching the remaining second insulation layer using the anti-bowing spacers and the hard masks as an etch mask to form third openings; and
etching the etch stop layer disposed beneath the third openings to form fourth openings exposing predetermined portions of the substrate.

21. The method of claim 20, wherein forming the second openings comprises using a gas mixture of CₓF_{y}/O₂ gas and an MERIE plasma source.

22. The method of claim 21, wherein the CₓF_{y} gas is selected from the group consisting of CF₄, C₄F₈, C₅F₈, CHF₃, and CH₂F₂.

23. A method for fabricating a semiconductor device, comprising:
forming an insulation layer on a substrate;
selectively etching the insulation layer to form first openings;
enlarging areas of the first openings;
forming anti-bowing spacers on sidewalls of the enlarged first openings;
etching portions of the insulation layer remaining beneath the enlarged first openings to form second openings;
forming lower electrodes on bottom portions and sidewalls of opening regions, each opening region ‘including the enlarged first opening and the second opening; and
sequentially forming a dielectric layer and an upper electrode on the lower electrodes.

24. The method of claim 23, wherein forming the insulation layer comprises:
forming a first insulation layer on the substrate;
forming an etch stop layer on the first insulation layer; and
forming a second insulation layer for use in a capacitor on the etch stop layer, the second insulation layer further comprising a third insulation layer and a fourth insulation layer.

25. The method of claim 24, wherein forming the first openings comprises:
forming hard masks on the fourth insulation layer; and
selectively etching the fourth insulation layer using the hard masks as an etch mask such that a portion of the fourth insulation layer having a predetermined thickness remains at the bottom of the first openings.

26. The method of claim 25, wherein forming the first insulation layer comprises forming a multi-layer structure.

27. The method of claim 25, wherein the third insulation layer includes phosphosilicate glass (PSG) and the fourth insulation layer includes tetraethyl orthosilicate (TEOS).

28. The method of claim 23, wherein the forming the first openings comprises injecting a gas mixture of CₓF_{y}/O₂ into a magnetically enhanced reactive ion etching (MERIE) plasma source.

29. The method of claim 28, wherein a ratio of a flow quantity of the CₓF_{y} gas to the O₂ gas is approximately 1 to 1.

30. The method of claim 29, wherein the CₓF_{y} gas is selected from the group consisting of CF₄, C₄F₈, C₄F₆, and C₅F₈.

31. The method of claim 23, wherein enlarging the areas of the first openings comprises employing an isotropic etching process using a wet chemical.

32. The method of claim 31, wherein the wet chemical is one of buffered oxide etchant (BOE) and hydrogen fluoride (HF).

33. The method of claim 31, wherein enlarging the areas of the first openings comprises enlarging the areas until a width between adjacent first openings is at least 10 nm.

34. The method of claim 24, wherein forming the anti-bowing spacers comprises:
forming an anti-bowing layer on the enlarged first openings and on the hard masks; and
selectively etching portions of the anti-bowing layer disposed on the hard masks and on bottom portions of the enlarged first openings to form the anti-bowing spacers on the sidewalls of the enlarged first openings.

35. The method of claim 34, wherein forming the anti-bowing layer comprises forming a layer comprising the same material used to form the lower electrodes, so that the anti-bowing layer prevents a bowing incidence and functions as the lower electrodes.

36. The method of claim 35, wherein forming the anti-bowing layer comprises forming a layer of a material selected from the group consisting of titanium nitride (TiN), tungsten (W), ruthenium (Ru), and iridium (Ir).

37. The method of claim 36, wherein the selective etching of the anti-bowing layer is carried out using a high density plasma obtained by injecting, a gas mixture of Cl₂/Ar gas in a predetermined ratio into a transformer coupled plasma (TCP)/inductively coupled plasma (ICP) plasma source.

38. The method of claim 37, wherein the predetermined mixing ratio of the Cl₂ gas to the Ar gas ranges between approximately 1:10 and approximately 1:20.

39. The method of claim 34, wherein the anti-bowing layer includes a nitride-based material.

40. The method of 39, wherein selective etching of the anti-bowing layer comprises using a high density plasma obtained by injecting a gas mixture of CₓF_{y}/CHₓF_{y}/O₂ into an MERIE plasma source.

41. The method of claim 34, wherein forming the anti-bowing layer comprises forming a layer to a thickness ranging from approximately 100 Å to approximately 200 Å.

42. The method of claim 25, wherein forming the second openings comprises:
etching the remaining second insulation layer using the anti-bowing spacers and the hard masks as an etch mask to form third openings; and
etching the etch stop layer disposed beneath the third openings to form fourth openings exposing predetermined portions of the substrate.

43. The method of claim 42, wherein forming the second openings is carried out’ using a gas mixture of CₓF_{y}/O₂ at an MERIE plasma source.

44. The method of claim 43, wherein the CₓF_{y} gas is selected from the group consisting of CF₄, C₄F₈, C₅F₈, CHF₃, and CH₂F₂.
